(19) United States
(12) Patent Application Publication
(10) Pub. No.: US 2025/0364511 A1
(43) Pub. Date: Nov. 27, 2025

(54) ELECTRONIC SYSTEM AND SEMICONDUCTOR MODULE

(71) Applicant: Advanced Semiconductor Engineering, Inc., Kaohsiung (TW)

(72) Inventors: Wei-Tung CHANG, Kaohsiung (TW); Hsin-Yu CHEN, Kaohsiung (TW)

(73) Assignee: Advanced Semiconductor Engineering, Inc., Kaohsiung (TW)

(21) Appl. No.: 18/674,710

(22) Filed: May 24, 2024

(51) Int. Cl. H01L 25/16; H01L 23/31; H01L 23/552; H01L 23/64

(52) U.S. Cl. CPC H01L 25/165; H01L 23/3107; H01L 23/552; H01L 23/642; H01L 23/647

(57) ABSTRACT

An electronic system and a semiconductor module is provided. The semiconductor module includes a carrier, a plurality of passive components, an electronic component, and an encapsulation layer. The plurality of passive components is disposed over the carrier. The electronic component is disposed over the carrier and configured to clamp a voltage of the semiconductor module. The encapsulation layer covers and contacts the plurality of passive components and the electronic component.

### BACKGROUND

### 1. Field of the Disclosure

The present disclosure relates to an electronic system and a semiconductor module.

### 2. Description of the Related Art

EOS (electrical overstress) protection circuits may include discrete components arranged side by side on a printed circuit board. However, such an arrangement can adversely increase the size of the circuits.

### SUMMARY

In some embodiments, a semiconductor module includes a carrier, a plurality of passive components, an electronic component, and an encapsulation layer. The plurality of passive components is disposed over the carrier. The electronic component is disposed over the carrier and configured to clamp a voltage of the semiconductor module. The encapsulation layer covers and contacts the plurality of passive components and the electronic component.

In some embodiments, a semiconductor module includes a carrier, a first device, and a second device. The carrier comprises a first wiring structure and a second wiring structure. The first die is electrically connected to the first wiring structure. The first device and the first wiring structure collectively define a first group. The second device is electrically connected to the second wiring structure. The second device and the second wiring structure collectively define a second group. The first group operates independent of the second group.

In some embodiments, an electronic system includes a plurality of passive components, a first electronic component, an encapsulation layer, and a second electronic component. The first electronic component is configured to clamp a voltage of the electronic system and has a first terminal. The encapsulation layer covers and contacts the plurality of passive components and the first electronic component. The second electronic component is electrically connected to the first terminal.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a schematic diagram of an electronic device according to some embodiments of the present disclosure.

FIG. 2 is a schematic diagram of an electronic device according to some embodiments of the present disclosure.

FIG. 3 is a schematic diagram of an electronic device according to some embodiments of the present disclosure.

FIG. 4 is a cross-section of a semiconductor module according to some embodiments of the present disclosure.

FIG. 4A is a cross-section of a semiconductor module according to some embodiments of the present disclosure.

FIG. 5A is a cross-section of a semiconductor module according to some embodiments of the present disclosure.

FIG. 5B is a cross-section along line 5B-5B′ of FIG. 5A.

FIG. 5C is a cross-section of a semiconductor module according to some embodiments of the present disclosure.

FIG. 5D is a cross-section along line 5D-5D′ of FIG. 5C.

FIG. 6A is a cross-section of a semiconductor module according to some embodiments of the present disclosure.

FIG. 6B is a cross-section along line 6B-6B′ of FIG. 6A.

FIG. 7A is a cross-section of a semiconductor module according to some embodiments of the present disclosure.

FIG. 7B is a cross-section along line 7B-7B′ of FIG. 7A.

FIGS. 8A, 8B, 8C, 8D, 8E, and 8F are three-dimensional views of a passive component according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

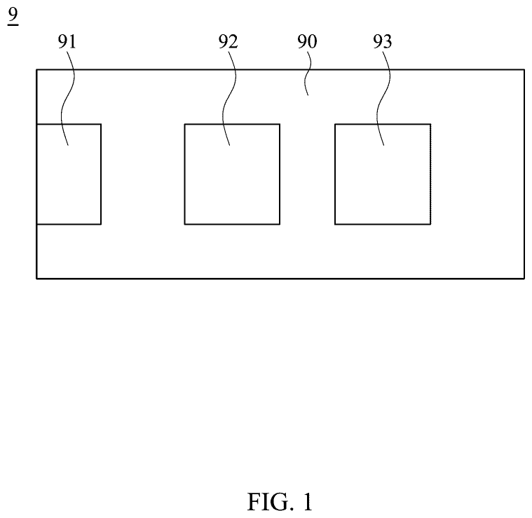

FIG. 1 is a schematic diagram of an electronic device 9 according to some embodiments of the present disclosure. The electronic device 9 may include a carrier 90, a connector 91, a passive component 92, and an electrostatic discharge (ESD) diode 93. The connector 91, the passive component 92, and the ESD diode 93 may be disposed over and electrically connected to the carrier 90.

The carrier 90 may be or include, for example, one or more of a printed circuit board, such as a paper-based copper foil laminate, a composite copper foil laminate, a polymer-impregnated glass-fiber-based copper foil laminate, and so on.

The connector 91 may include a port for connecting an external device, such as a mobile phone, a computer, a keyboard, a mouse, a printer, and/or a charger. The connector 91 may include an USB port.

The passive component 92 and the ESD diode 93 are discrete components. The passive component 92 may be individually mounted on the carrier 90 and the ESD diode 93 may be individually mounted on the carrier 90. The passive component 92 is spaced apart from the ESD diode 93 by a predetermined distance, such that they do not overlap/influence each other during mounting. The passive component 92 may electrically connect to the ESD diode 93 through the carrier 90. The connector 91 may be configured to receive an electrical signal. In some cases, the electrical signal may carry an unexpectedly high voltage, creating an EOS (electrical overstress) event. The passive component 92 and the ESD diode 93 may together protect the electronic device 9 from the event.

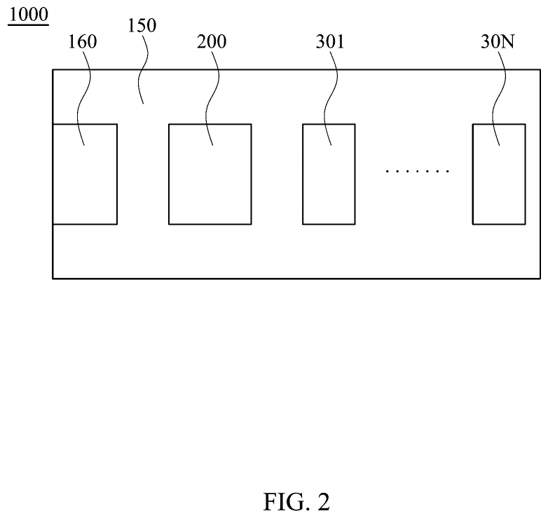

FIG. 2 is a schematic diagram of an electronic device (or an electronic system) 1000 according to some embodiments of the present disclosure. The electronic device (or the electronic system) 1000 may include a carrier 150, a connector 160, a semiconductor module 200, and a plurality of semiconductor dies 301, . . . , 30N, wherein N is a positive integer greater than 1. The connector 160, the semiconductor module 200, and the semiconductor dies 301, . . . , 30N may be disposed over and electrically connected to the carrier 150.

The carrier 150 may be or include, for example, one or more of a printed circuit board, such as a paper-based copper foil laminate, a composite copper foil laminate, a polymer-impregnated glass-fiber-based copper foil laminate, and so on.

The connector 160 may include a port for connecting an external device, such as a mobile phone, a computer, a keyboard, a mouse, a printer, and/or a charger. The connector 160 may include an USB port.

In some embodiments, the semiconductor dies 301, . . . , 30N may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the semiconductor dies 301, . . . , 30N may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like. The memory element may be a cache memory.

The semiconductor module 200 may electrically connect to the connector 160. The semiconductor module 200 may electrically connect between the connector 160 and at least one of the semiconductor dies 301, . . . , 30N. The connector 160 may be configured to receive an electrical signal. In some cases, the electrical signal may carry an unexpectedly high voltage (i.e., an EOS event). The semiconductor module 200 may be configured to protect the semiconductor dies 301, . . . , 30N from EOS events.

The EOS events may be result from the following cases: (1) interference between electrical sources, noise, or over-voltage; (2) transient current/peak/interference during a hot switching; (3) lightning; (4) glitch/pulse during a test; (5) a shabby circuit design; (6) interference from other equipment; (7) inadequate operating steps; and (8) insufficient number of the grounding.

In some cases, a passive component (e.g., 92) and an ESD diode (e.g., 93) are discrete components individually mounted on a printed circuit board (e.g., 90). In FIG. 2, the semiconductor module 200 may include an integrated EOS protection circuit, which includes a passive component and an ESD diode. The passive component and the ESD diode are integrated into and additional carrier (e.g., redistribution layer structure) prior to being mounted on the carrier 150. The discrete passive component (e.g., 92) and ESD diode (e.g., 93) are separated by a predetermined distance, while the semiconductor module 200 integrates the passive component and the ESD diode in advance. Therefore, the semiconductor module 200 may occupy a smaller area over the carrier 150 than that of the passive component (e.g., 92) and the ESD diode (e.g., 93) over the carrier (e.g., 90).

In some embodiments, the semiconductor module 200 may be configured to amplify the electrical signal from the connector 160. In some embodiments, the semiconductor module 200 may be configured to clamp the electrical signal from the connector 160. In some embodiments, the semiconductor module 200 may be configured to provide a clock signal to the semiconductor dies 301, . . . , 30N.

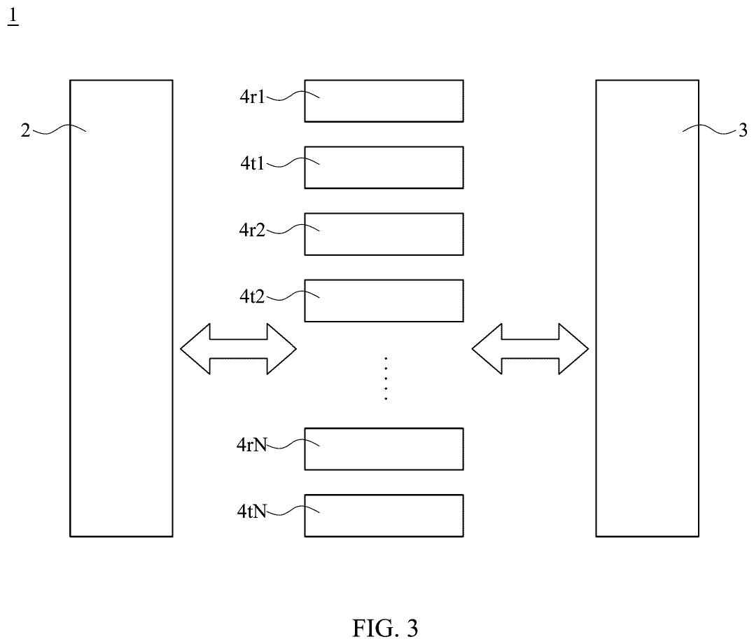

FIG. 3 is a schematic diagram of an electronic device (or an electronic system) 1 according to some embodiments of the present disclosure. The electronic device (or the electronic system) 1 may include a connector 2, a plurality of receivers 4r1, 4r2, . . . , 4rN, a plurality of transmitters 4t1, 4t2, . . . , 4tN, and an electronic component 3.

The connector 1 may include a port for connecting an external device, such as a mobile phone, a computer, a keyboard, a mouse, a printer, and/or a charger. The connector 1 may include an USB port.

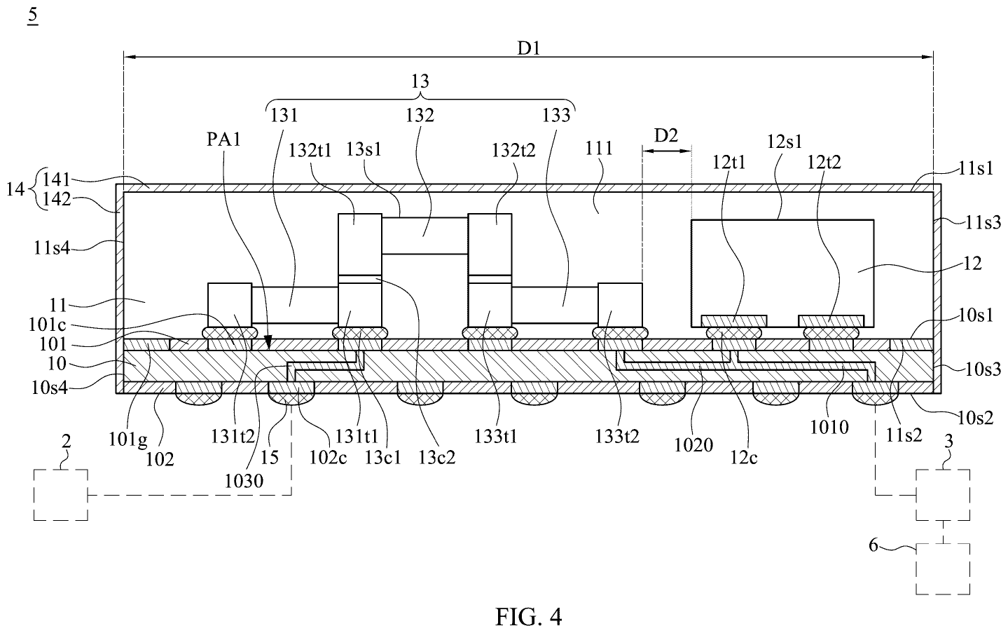

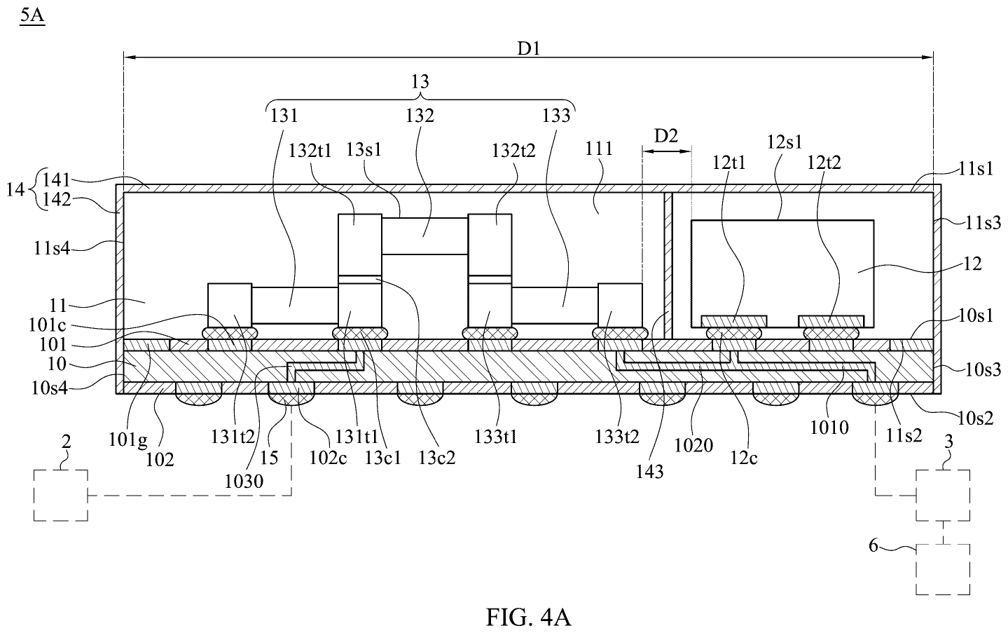

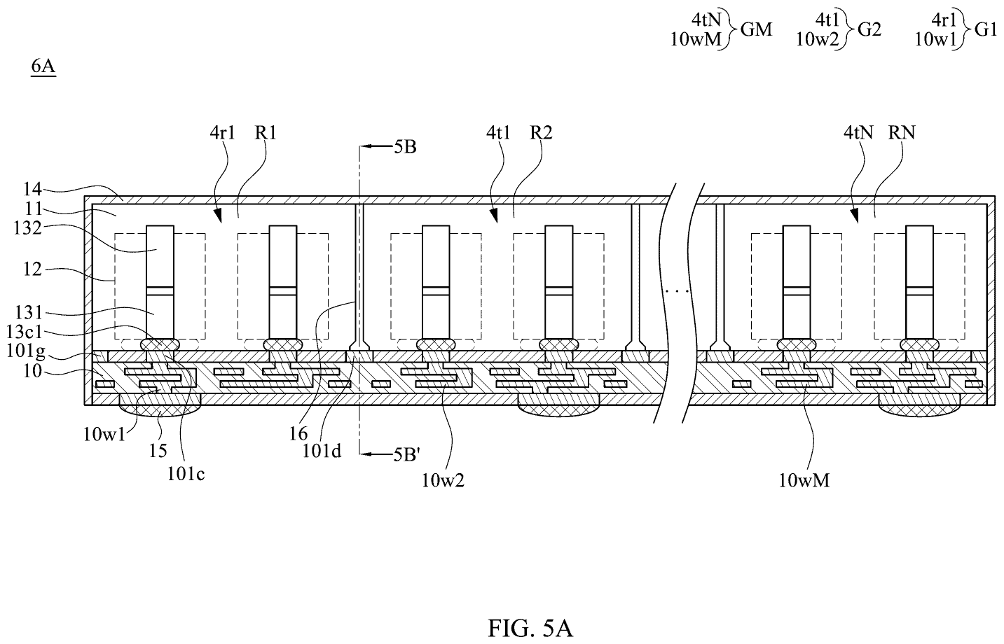

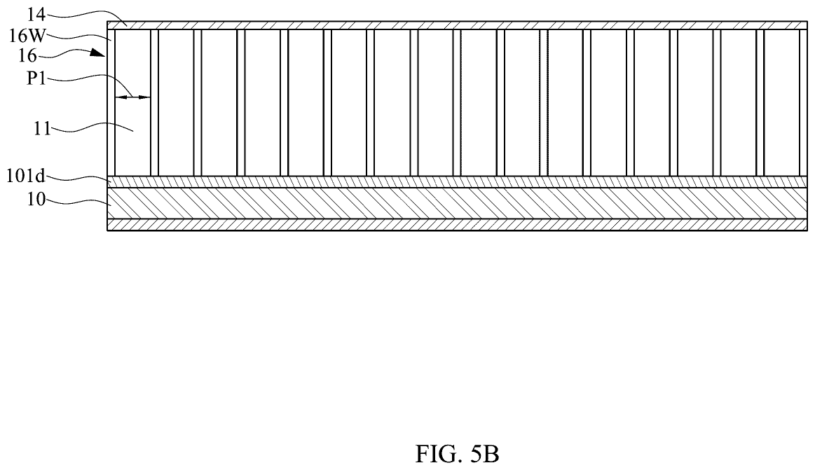

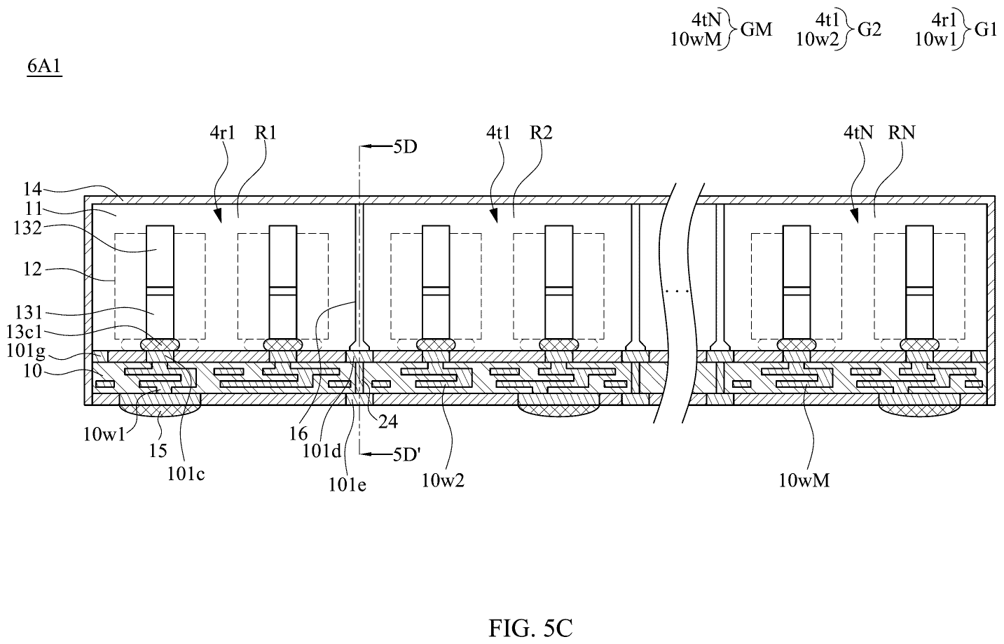

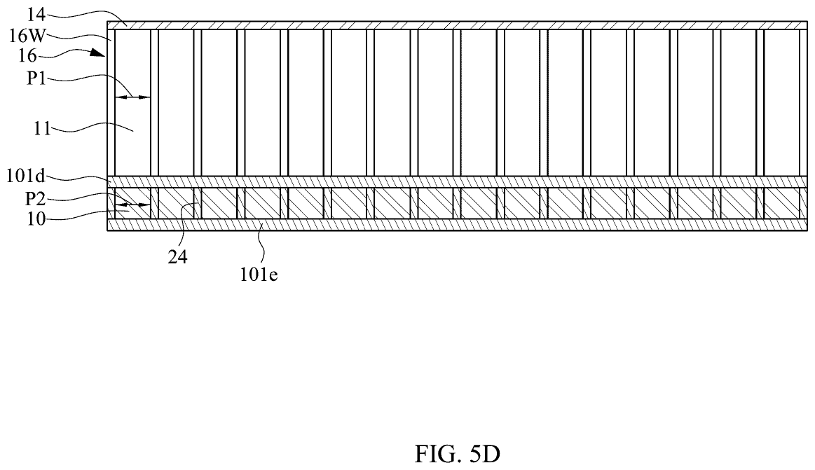

The receivers 4r1, 4r2, . . . , 4rN and the transmitters 4t1, 4t2, . . . , 4tN may be included in a semiconductor module (e.g., the semiconductor module 200 of FIG. 2). Structural details of the receivers 4r1, 4r2, . . . , 4rN and the transmitters 4t1, 4t2, . . . , 4tN are provided in descriptions of FIG. 4, FIGS. 5A and 5B, FIGS. 6A and 6B, FIGS. 7A and 7B, and FIGS. 8A-8F.

The receivers 4r1, 4r2, . . . , 4rN may be configured to receive electrical signals from the connector 1. The receivers 4r1, 4r2, . . . , 4rN may be responsible for a respective channel of the connector 1. The transmitters 4t1, 4t2, . . . , 4tN may be configured to transmit electrical signals to the connector 1. The transmitters 4t1, 4t2, . . . , 4tN may be responsible for a respective channel of the connector 1. The receivers 4r1, 4r2, . . . , 4rN and the transmitters 4t1, 4t2, . . . , 4tN may be arranged alternately in order but does not limit the scope of the present disclosure. In some embodiments, the arrangement of the receivers 4r1, 4r2, . . . , 4rN may be arranged in sequence and the arrangement of the transmitters 4t1, 4t2, . . . , 4tN may follow the receivers 4r1, 4r2, . . . , 4rN. In some embodiments, the arrangement of the transmitters 4t1, 4t2, . . . , 4tN may be arranged in sequence and the arrangement of the receivers 4r1, 4r2, . . . , 4rN may follow the transmitters 4t1, 4t2, . . . , 4tN.

The electronic component 3 may include, for example, a central processing unit (CPU), a microprocessor unit (MPU), a graphics processing unit (GPU), a microcontroller unit (MCU), an application-specific integrated circuit (ASIC), a field-programmable gate array (FPGA), or another type of integrated circuit. In some embodiments, the electronic component 3 may include one or more processing elements and one or more memory elements electrically connected to the processing elements. The processing element(s) and the memory element(s) may be divided from or originate in a monolithic processing unit (e.g., a CPU, a MPU, a GPU, a MCU, an ASIC, or the like). In some embodiments, the processing element may be a CPU chiplet, a MCU chiplet, a GPU chiplet, an ASIC chiplet, or the like. The memory element may be a cache memory.

In some embodiments, the electronic component 3 may include a re-timer configured to reshape and retime signals from the connector 1 to reduce jitter and other timing issues. In some embodiments, the re-timer may include a clock data recovery (CDR) circuit, a phase-locked loop (PLL), and a digital signal processing (DSP) circuit. These components work together to clean and reshape incoming signals from the connector 1 to improve overall signal integrity. The re-timer may provide a clock signal by receiving an input clock signal and using internal circuitry (e.g., CDR circuit) to clean up and regenerate the signal.

Each of the transmitters 4t1, 4t2, . . . , 4tN and the receivers 4r1, 4r2, . . . , 4rN may include an EOS protection circuit to protect the electronic component 3 and/or an external electronic component connected to the connector 1.

FIG. 4 is a cross-section of a semiconductor module 5 according to some embodiments of the present disclosure. The semiconductor module 5 may be the semiconductor module 200 of the electronic device 1000 of FIG. 2. The cross-section of the semiconductor module 5 may be one of the cross-section of the transmitters 4t1, 4t2, . . . , 4tN and the receivers 4r1, 4r2, . . . , 4rN.

The semiconductor module 5 may include a carrier 10, an encapsulation layer 11, an electronic component 12, a plurality of passive components 13, and a shield 14. The semiconductor module 5 may be configured to protect an external electronic component (e.g., the semiconductor dies 301, . . . , 30N and the electronic component 3) from an EOS event, e.g., from a connector (e.g., the connector 160 or the connector 1).

In some embodiments, the semiconductor module 5 may be configured to amplify the electrical signal from a connector (e.g., the connector 160 or the connector 1). In some embodiments, the semiconductor module 5 may be configured to clamp the electrical signal from a connector (e.g., the connector 160 or the connector 1). In some embodiments, the semiconductor module 5 may be configured to provide a clock signal to an external electronic component (e.g., the semiconductor dies 301, . . . , 30N and the electronic component 3).

The carrier (or a circuit structure, a substrate) 10 may be or include, for example, one or more of a printed circuit board, such as a paper-based copper foil laminate, a composite copper foil laminate, a polymer-impregnated glass-fiber-based copper foil laminate, and so on. The carrier 10 may include a dielectric layer and an interconnection structure, such as a redistribution layer (RDL) and/or a grounding element.

The carrier 10 may have a surface (or a top surface) 10s1 and a surface (or a bottom surface) 10s2 opposite to the surface 10s1. The surface 10s1 may be covered and in contact with encapsulation layer 11. The surface 10s1 may face the electronic component 12, the passive components 13, and the encapsulation layer 11. The surface 10s2 may face away from the electronic component 12, the passive components 13, and the encapsulation layer 11.

The carrier 10 may include a protection layer 101 and a protection layer 102 opposite to the protection layer 101. The protection layer 101 may include a photoresist layer. The protection layer 102 may include a photoresist layer. The protection layer 101 may be disposed at the surface 10s1 of the carrier 10 and the protection layer 102 may be disposed at the surface 10s2 of the carrier 10. The carrier 10 may include a plurality of pads 101c disposed at the surface 10s1 of the carrier 10. The pads 101c may be enclosed by the protection layer 101. The pads 101c may electrically connect to the interconnection structure of the carrier 10. The carrier 10 may include a plurality of pads 102c disposed at the surface 10s2 of the carrier 10. The pads 102c may be enclosed by the protection layer 102. The pads 102c may electrically connect to the interconnection structure of the carrier 10. The pads 101c may be metal, such as copper, gold, silver, aluminum, titanium, tantalum, or the like. The pads 102c may be metal, such as copper, gold, silver, aluminum, titanium, tantalum, or the like.

The semiconductor module 5 may further include a plurality of connection elements 15 disposed below the carrier 10. The connection elements 15 may be connected to the pads 102c. The connection elements 15 may be mounted on an external circuit board (e.g., the carrier 150 in FIG. 2). The carrier 10 may electrically connect to an external circuit board (e.g., the carrier 150 in FIG. 2). The semiconductor module 5 may be configured to provide EOS protection for at least one semiconductor die (e.g., 301 to 30N in FIG. 2) on the external printed circuit board. The connection elements 15 may include solder balls, controlled collapse chip connection (C4) bumps, a ball grid array (BGA), or a land grid array (LGA).

The electronic component 12 may be disposed over the carrier 10 (or the surface 10s1 of the carrier 10). The electronic component 12 may be covered by the encapsulation layer 11. The electronic component 12 may be in contact with the encapsulation layer 11. The electronic component 12 may include a first terminal 12t1 and a second terminal 12t2. The first terminal 12t1 may be closer to the passive components 13 than the second terminal 12t2. The semiconductor module 5 may further include a plurality of connection elements 12c disposed over the surface 10s1 of the carrier 10. The connection elements 12c may be mounted on the pads 101c. The first terminal 12t1 and the second terminal 12t2 of the electronic component 12 may electrically connect to the carrier 10 through the connection elements 12c. The connection elements 12c may include solder balls, controlled collapse chip connection (C4) bumps, a ball grid array (BGA), or a land grid array (LGA).

In some embodiments, the electronic component 12 may include an ESD device. The electronic component 12 may include a voltage-clamping component. The electronic component 12 may include a diode. The electronic component 12 may include a Zener diode. The electronic component 12 may be configured to clamp a voltage of the semiconductor module 5. The electronic component 12 may be configured to provide a low impedance path in the semiconductor module 5.

In some embodiments, the semiconductor module 5 may be included in an electronic system, which may further include a second electronic component (e.g., the connector 2), a third electronic component (e.g., the electronic component 3), and a device 6 (e.g., one of the semiconductor dies 301, . . . , 30N of FIG. 2). In some embodiments, the electronic component 2 may be configured to block a signal from the second electronic component (e.g., the connector 2) to the third electronic component (e.g., the electronic component 3) when a voltage difference between the first terminal 12t1 and the second terminal 12t2 of the electronic component 12 exceeds a predetermined value. The signal is transmitted through the passive components 13 and the electronic component 12. The predetermined value may be a breakdown voltage of a Zener diode.

The passive components 13 may be disposed over the carrier 10 (or the surface 10s1 of the carrier 10). The passive components 13 may be disposed adjacent to the electronic component 12. The passive components 13 may be covered by the encapsulation layer 11. The passive components 13 may be in contact with the encapsulation layer 11. The semiconductor module 5 may further include a plurality of connection elements 13cl disposed over the surface 10s1 of the carrier 10. The connection elements 13cl may be mounted on the pads 101c. The passive components 13 may electrically connect to the carrier 10 through the connection elements 13c1. The connection elements 13cl may include solder balls, controlled collapse chip connection (C4) bumps, a ball grid array (BGA), or a land grid array (LGA).

The passive components 13 may include a top surface 13s1 facing the shield 14. The electronic component 12 may include a top surface 12s1 facing the shield 14. The top surface 13s1 of the passive components 13 may be higher than the top surface 12s1 of the electronic component 12 with respect to the surface 10s1 of the carrier 10. In some embodiments, a first elevation of the top surface 13s1 of a capacitor (e.g., 132) of the passive components 13 may be higher than or substantially the same as a second elevation of the top surface 12s1 of the electronic component 2 with respect to the carrier 10.

The passive components 13 may include a first passive component 131, a second passive component 132, and a third passive component 133. The second passive component 132 may be disposed over the first passive component 131 in cross-section. The second passive component 132 may be disposed over the third passive component 133 in cross-section. The first passive component 131 and the third passive component 133 may be disposed below the second passive component 132. The third passive component 133 and the first passive component 131 may be on the same horizontal plane. The second passive component 132 and the first passive component 131 may be on different horizontal planes. The second passive component 132 and the third passive component 133 may be on different horizontal planes. The first passive component 131 may include a first terminal 131t1 and a second terminal 131t2 connected to the connection elements 13c1. The third passive component 133 may include a first terminal 133t1 and a second terminal 133t2 connected to the connection elements 13cl. The second passive component 132 may include a first terminal 132t1 and a second terminal 132t2. The first terminal 132t1 of the second passive component 132 may be connected to the first terminal 131t1 of the first passive component 131. The first terminal 132t1 may be connected to the first terminal 131t1 through a connection element 13c2. The connection element 13c2 may include a solder bump or an electrically conductive adhesive layer. The connection element 13cl may include material different from the connection element 13c2. In some embodiments, the connection element 13cl may include the same material as the connection element 13c2.

The second terminal 132t2 of the second passive component 132 may be connected to the first terminal 133t1 of the third passive component 133. The second terminal 132t2 may be connected to the first terminal 133t1 through a connection element 13c2. The first terminal 132t1 of the second passive component 132 may overlap the first terminal 131t1 of the first passive component 131 perpendicular to the top surface 13s1 of the passive components 13. The second terminal 132t2 of the second passive component 132 may overlap the first terminal 133t1 of the third passive component 133 perpendicular to the top surface 13s1 of the passive components 13.

The passive components 13 may include an EOS circuit. The passive components 13 may include a first resistor (e.g., 133), a second resistor (e.g., 131), and a capacitor (e.g., 132). The first resistor and the second resistor may electrically connect to the capacitor. The second resistor may be connected to the ground and the first resistor may be connected to the electronic component 12.

In some embodiments, the first terminal 12t1 of the electronic component 12 may be connected to the second terminal 133t2 of the passive component (or the first resistor) 133. The first terminal 12t1 of the electronic component 12 may be electrically connected to the second electronic component (e.g., the electronic component 3). The second terminal 12t2 of the electronic component 12 may be electrically connected to the ground. The first terminal 131t1 of the passive components 13 (or the passive component 131) may be electrically connected to the third electronic component (e.g., the connector 2). The first terminal 131t1 of the passive component 131 may be electrically connected to the first terminal 132t1 of the passive component 132. The second terminal 131t2 of the passive component 131 may be electrically connected to the ground.

In some embodiments, the carrier 10 may include a wiring structure 1010, a wiring structure 1020, and a wiring structure 1030. The wiring structure 1010 may electrically connect the first terminal 12t1 of the electronic component 12 to one or more of the connection elements 15. The wiring structure 1010 may electrically connect the electronic component 12 to the second electronic component (e.g., the electronic component 3). The wiring structure 1020 may electrically connect the first terminal 12t1 of the electronic component 12 to the second terminal 133t2 of the passive component (or the first resistor) 133. The wiring structure 1030 may electrically connect the first terminal 131t1 of the passive component (or the second resistor) 131 to one or more of the connection elements 15. The wiring structure 1030 may electrically connect the passive components 13 to the third electronic component (e.g., the connector 2).

In some embodiments, the second electronic component (e.g., the electronic component 3) may be electrically connected to the device 6. The device 6 may be one of the semiconductor dies 301, . . . , 30N. The device 6 may include a power management IC, radio frequency IC, driver IC, controller IC, or the like. The second electronic component (e.g., the electronic component 3) may be configured to synchronize a first signal transmitted from the third electronic component (e.g., the connector 2) to the device 6 and a second signal transmitted from the device 6 to the third electronic component (e.g., the connector 2).

The encapsulation layer 11 may include a top surface 11s1. The encapsulation layer 11 may be higher than the top surface 12s1 of the electronic component 12 and the top surface 13s1 of the passive components 13. The encapsulation layer 11 may have a portion 111 disposed between the shield 14 and the passive components 13 (or between the shield 14 and the electronic component 12). The portion 111 indicates a clearance molding area to make sure that the passive components 13 and the electronic component 12 are covered by the encapsulation layer 11.

In some embodiments, a projection area PAI of the encapsulation layer 11 on the carrier 10 may cover an electrical transmission path (e.g., the wiring structure 1020) between the first terminal 12t1 of the electronic component 12 and the second terminal 133t2 of the passive component (or the first resistor) 133. The encapsulation layer 11 may vertically, with respect to the carrier 10, cover the electrical transmission path (e.g., the wiring structure 1020) connecting the first terminal 12t1 of the electronic component 12 and the second terminal 133t2 of the passive component (or the first resistor) 133.

The encapsulation layer 11 may include an epoxy resin including fillers, a molding compound (e.g., an epoxy molding compound or other molding compound), polyimide, a phenolic compound or material, a material including silicone dispersed therein, or a combination thereof. The encapsulation layer 11 may be electrically insulative.

The encapsulation layer 11 may cover and directly contact the passive components 13 and the electronic component 12. The encapsulation layer 11 may have a first lateral surface 11s3 and a second lateral surface 11s4 both connected to the top surface 11s1 of the encapsulation layer 11. A first distance D1 between the first lateral surface 11s3 and the second lateral surface 11s4 of the encapsulation layer 11 may be greater than a second distance D2 between the passive components 13 and the electronic component 12.

The carrier 10 may have a first lateral surface 10s3 and a second lateral surface 10s4 opposite to the first lateral surface 10s3. The first lateral surface 10s3 of the carrier 10 may be aligned with the first lateral surface 11s3 of the encapsulation layer 11. The first lateral surface 10s3 of the carrier 10 and the first lateral surface 11s3 of the encapsulation layer 11 may be substantially coplanar. The second lateral surface 10s4 of the carrier 10 may be aligned with the second lateral surface 11s4 of the encapsulation layer 11. The second lateral surface 10s4 of the carrier 10 and the second lateral surface 11s4 of the encapsulation layer 11 may be substantially coplanar.

The shield 14 may be disposed over the plurality of surfaces of the encapsulation layer 11. The shield 14 may be disposed over the top surface 11s1, the first lateral surface 11s3, and the second lateral surface 11s4 of the encapsulation layer 11. The shield 14 may cover the encapsulation layer 11. The shield 14 may conformally cover the encapsulation layer 11. The shield 14 may be disposed over the first lateral surface 10s3 and the second lateral surface 10s4 of the carrier 10. The shield 14 may be formed by coating a conductive material on the top surface 11s1, the first lateral surface 11s3, the second lateral surface 11s4, the first lateral surface 10s3, the second lateral surface 10s4.

The carrier 10 may further include at least one grounding pad 101g disposed at the surface 10s1 of the carrier 10. The grounding pad 101g may be connected to the ground. The grounding pad 101g may be exposed by the first lateral surface 10s3 and the second lateral surface 10s4 of the carrier 10. The shield 14 may be in contact with the grounding pad 101g. The shield 14 may electrically connect to the grounding pad 101g. The potential of the shield 14 may be connected to the ground. The shield 14 may be configured to shield the passive components 13 and the electronic component 12 from an external environment.

The shield 14 may include a top portion 141 and a side portion 142 substantially vertical to the top portion 141. The top portion 141 and the side portion 142 collectively define a space for accommodating the passive components 13 and the electronic component 12. The top portion 141 may be connected to the side portion 142. The top portion 141 may be disposed over the top surface 11s1. The side portion 142 may be disposed over the first lateral surface 11s3 and the second lateral surface 11s4.

The second passive component 132 is stacked over the first passive component 131 and the third passive component 133. The X-Y dimension of the passive components 13 can be relatively smaller than passive components arranged at the same plane. The passive components 13 may be higher than the electronic component 12, but still shorter than the encapsulation layer 11.

The semiconductor module 5 integrates the passive components 13 and the electronic component 12 onto the carrier 10. The passive components 13 and the electronic component 12 are encapsulated by a single encapsulation layer (e.g., the encapsulation layer 11) and shielded by a single shield (e.g., the shield 14). Hence, the semiconductor module 5 can be smaller than discrete components (e.g., the passive component 92 and the ESD diode 93 of the electronic device 9). The semiconductor module 5 occupies a smaller area over a printed circuit board (e.g., the carrier 150) than the passive component (e.g., 92) and the ESD diode (e.g., 93) over the carrier (e.g., 90).

FIG. 4A is a cross-section of a semiconductor module 5A according to some embodiments of the present disclosure. The semiconductor module 5A of FIG. 4A is similar to the semiconductor module 5 in FIG. 4. Therefore, some detailed descriptions may refer to corresponding preceding paragraphs and are not repeated hereinafter for conciseness, with differences therebetween as follows.

The semiconductor module 5A may further include a shield 143 disposed between the passive components 13 and the electronic component 12. The shield 143 may be connected to the top portion 141 of the shield 14. The shield 143 may be connected to the ground through the shield 14. The shield 143 may be configured to shield the passive components 13 from the electronic component 12, or vice versa. The shield 143 may include a bond wiring, a conductive pillar, a conductive via, or a conductive sheet. The shield 143 may be made of metal, such as copper, gold, silver, aluminum, titanium, tantalum, or the like.

FIG. 5A is a cross-section of a semiconductor module 6A according to some embodiments of the present disclosure. The semiconductor module 6A may be the semiconductor module 200 of the electronic device 1000 o FIG. 2. The cross-section of the semiconductor module 6A may be along the arrangement of the transmitters 4t1, 4t2, . . . , 4tN and the receivers 4r1, 4r2, . . . , 4rN.

The semiconductor module 6A may include the carrier 10, the encapsulation layer 11, the electronic component 12, the passive components 13, and the shield 14. The carrier 10, the encapsulation layer 11, the electronic component 12, the passive components 13, and the shield 14 may be similar to those of the semiconductor module 5. Therefore, some detailed descriptions may refer to corresponding preceding paragraphs and are not repeated hereinafter for conciseness, with differences therebetween as follows.

The semiconductor module 6A may be configured to protect an external electronic component (e.g., the semiconductor dies 301, . . . , 30N and the electronic component 3) from an EOS event, e.g., from a connector (e.g., the connector 160 or the connector 1).

In some embodiments, the semiconductor module 6A may be configured to clamp the electrical signal from a connector (e.g., the connector 160 or the connector 1).

As shown in FIG. 5A, the semiconductor module 6A may include a plurality of regions R1, R2, . . . , RN independent. The regions R1, R2, . . . , RN may be configured to provide different functions. The semiconductor module 6A may include a compartment 16 disposed over the carrier 10. The compartment 16 may separate the regions R1, R2, . . . , RN. The compartment 16 may be configured to reduce the interference or crosstalk among the regions R1, R2, . . . , RN.

The regions R1, R2, . . . , RN may include a first region R1 in which a first receiver 4r1 is disposed and a second region R2 in which a first transmitter 4t2 is disposed. The first receiver 4r1 and the first transmitter 4t1 may be configured to process signals from different external electronic components. The regions R1, R2, . . . , RN may include an N^{th} region RN in which an N^{th} transmitter 4tN is disposed. The regions R1, R2, . . . , RN may include an N−1^{th} region RN in which an N^{th} receiver 4rN is disposed.

The compartment 16 may be in contact with the shield 14. The shield 14 may be disposed over the compartment 16. The compartment 16 may electrically connect to the shield 14. Hence, the compartment 16 and the shield 14 may be connected to the ground. The ground compartment 16 and the ground shield 14 may be configured to shield the signals in each of the regions R1, R2, . . . , RN from other regions or an external environment. Owing to the shield of the compartment 16, the signals processed in the regions R1, R2, . . . , RN (or the first receiver 4r1, the first transmitter 4t1, and the N^{th} transmitter 4tN) would not be interfered with each other.

In some embodiments, the receiver 4r1 may include the passive components 13 and the electronic component 12. The receiver 4r1 may include additional passive components similar to and arranged parallel to the passive components 13. The receiver 4r1 may include additional electronic components similar to and arranged parallel to the electronic component 12. The passive components 13 and the electronic component 12 may be responsible for the signals input into the receiver 4r1. The additional component and the additional electronic component may be responsible for the signals output from the receiver 4r1.

The compartment 16 may include a conductive material, such as metal. FIG. 5B is a cross-section along line 5B-5B′ of FIG. 5A. FIG. 5B illustrates the structure of the compartment 16 according to some embodiments of the present disclosure.

The compartment 16 may include a plurality of conductive wires 16w (e.g., bonding wires) arranged in a grating arrangement (or a fence). The conductive wires 16w may be metal, such as copper, gold, silver, aluminum, titanium, tantalum, or the like. The conductive wires 16w may be on a landing pad 101d of the carrier 10. The landing pad 101d may be metal, such as copper, gold, silver, aluminum, titanium, tantalum, or the like.

The conductive wires 16w have a pitch P1. The pitch P1 of the conductive wires 16w may be filled with the encapsulation layer 11. The conductive wires 16w of the compartment 16 may be configured to block an electromagnetic wave with a predetermined wavelength which is greater than the pitch P1. The pitch P1 may be smaller than the predetermined wavelength of the electromagnetic wave corresponding to the signals processed in one or more of the regions R1, R2, . . . , RN. Therefore, the electromagnetic wave in one of the regions R1, R2, . . . , RN will not interfere with the adjacent one of regions R1, R2, . . . , RN.

The conductive wires 16w of the compartment 16 may be substantially vertical to the surface 10s1 of the carrier 10. The conductive wires 16w of the compartment 16 may be substantially vertical to the top portion 141 of the shield 14. The conductive wires 16w of the compartment 16 may be higher than the passive components 13 and the electronic component 12 such that the conductive wires 16w can improve the shielding effect.

In some embodiments, the carrier 10 may include a plurality of wiring structures 10w1, 10w2, . . . , 10wM. Each of the wiring structures 10w1, 10w2, . . . , 10wM may correspond to a respective one of a plurality of devices above the carrier 10 (e.g., the transmitters 4t1, 4t2, . . . , 4tN and the receivers 4r1, 4r2, . . . , 4rN). The wiring structure 10w1 may be directly disposed below the receiver 4r1. The wiring structure 10w2 may be directly disposed below the transmitter 4t1. The wiring structure 10wM may be directly disposed below the transmitter 4tN.

The receiver 4r1 (or a first device) may be electrically connected to the wiring structure 10w1. The receiver 4r1 (or the first device) and the wiring structure 10w1 may collectively define a first group G1. The transmitter 4t1 (or a second device) may be electrically connected to the wiring structure 10w2. The transmitter 4t1 (or the second device) and the wiring structure 10w2 may collectively define a second group G2. The transmitter 4tN (or an N^{th} device) may be electrically connected to the wiring structure 10wM. The transmitter 4tN (or the N^{th} device) and the wiring structure 10wM may collectively define an M^{th} group GM. The groups G1, G2, . . . , GM independently operate. The first group G1 may operate independent of the second group G2.

In some embodiments, the wiring structure 10w1 may be free from being electrically connected to the transmitter 4t1 (or the second device), and the wiring structure 10w2 may be free from being electrically connected to the receiver 4r1 (or the first device).

The groups G1, G2, . . . , GM may be configured to respectively process the signals transmitted between a first external electronic component (e.g., the connector 2 in FIG. 3) and a second external electronic component (e.g., the electronic component 3 in FIG. 3). In other words, the groups G1, G2, . . . , GM may be responsible for a respective channel between the first external electronic component (e.g., the connector 2 in FIG. 3) and the second external electronic component (e.g., the electronic component 3 in FIG. 3). In some embodiments, the first group G1 may be configured to process a first signal transmitted from the first external electronic component (e.g., the connector 2 in FIG. 3) to the second external electronic component (e.g., the electronic component 3 in FIG. 3). The second group G2 may be configured to process a second signal transmitted from the second external electronic component (e.g., the electronic component 3 in FIG. 3) to the first external electronic component (e.g., the connector 2 in FIG. 3). Owing that the groups G1, G2, . . . , GM operate independent from each other, the signals transmitted therethrough would not interfere with each other, and the noise can be improved.

FIG. 5C is a cross-section of a semiconductor module 6A1 according to some embodiments of the present disclosure. FIG. 5D is a cross-section along line 5D-5D′ of FIG. 5C. The semiconductor module 6A1 of FIG. 5C and FIG. 5D is similar to the semiconductor module 6A in FIG. 5A and FIG. 5B. Therefore, some detailed descriptions may refer to corresponding preceding paragraphs and are not repeated hereinafter for conciseness, with differences therebetween as follows.

The semiconductor module 6A1 may further include a shield 24 disposed in the carrier 10. The carrier 10 of the semiconductor module 6A1 may include a conductive pad 101e. The shield 24 may be disposed on the conductive pad 101e. The shield may be disposed between the landing pad 101d and the conductive pad 101e.

The shield 24 may include a plurality of vias as shown in FIG. 5D. The vias of the shield 24 may have a pitch P2. The vias of the shield 24 may be configured to block an electromagnetic wave with a predetermined wavelength which is greater than the pitch P2. The pitch P2 may be smaller than the predetermined wavelength of the electromagnetic wave corresponding to the signals processed in one or more of the wiring structures 10w1, 10w2, and 10wM. Therefore, the electromagnetic wave in one of the wiring structures 10w1, 10w2, and 10wM would not interfere with the adjacent one wiring structure.

The shield 24 may be metal, such as copper, gold, silver, aluminum, titanium, tantalum, or the like. The conductive pad 101e may be metal, such as copper, gold, silver, aluminum, titanium, tantalum, or the like.

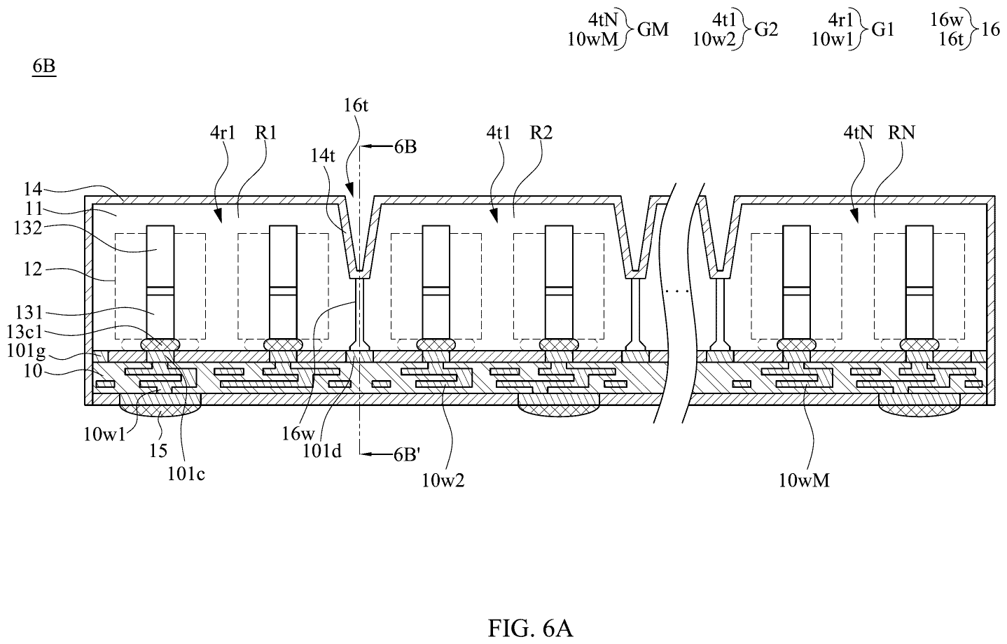

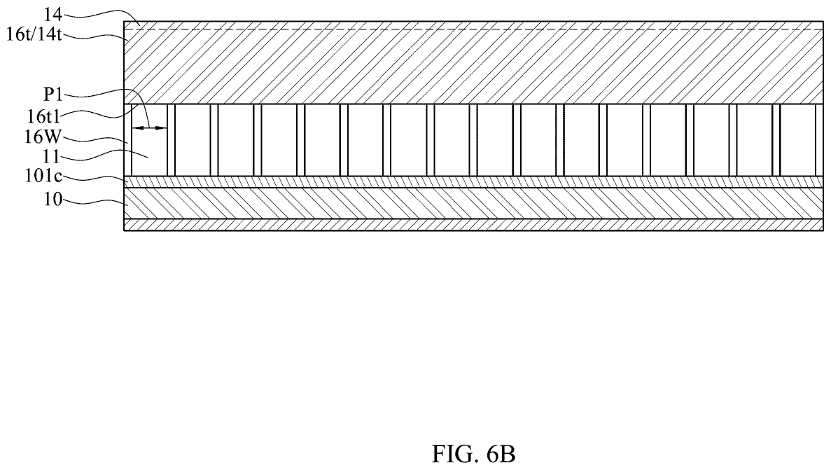

FIG. 6A is a cross-section of a semiconductor module 6B according to some embodiments of the present disclosure. The semiconductor module 6B of FIG. 6A is similar to the semiconductor module 6A in FIG. 5A. Therefore, some detailed descriptions may refer to corresponding preceding paragraphs and are not repeated hereinafter for conciseness, with differences therebetween as follows.

The compartment 16 of the semiconductor module 6B may further include a plurality of trenches 16t. The trenches 16t may be disposed over the conductive wires 16w. The trenches 16t may be coated with a conductive layer 14t. The sidewalls of the trenches 16t may be covered by the conductive layer 14t. Each of the trenches 16t may be connected to the grating arrangement (or the fence) of the bond wiring 16w. The trenches 16t may be formed by etching a portion of the encapsulation layer 11 with a laser. The trenches 16t may have a tapered profile toward the conductive wires 16w. The conductive layer 14t may be included in the shield 14. The top portion 141 may be connected to the conductive layer 14t.

FIG. 6B is a cross-section along line 6B-6B′ of FIG. 6A. The trenches 16t may extend along the grating arrangement (or the fence) of the conductive wires 16w. The trenches 16t may have a bottom surface 16t1 partially in contact with the conductive wires 16w and the encapsulation layer 11 in the pitch P1. Owing to the shielding of the compartment 16, the signals processed in the regions R1, R2, . . . , RN (or the first receiver 4r1, the first transmitter 4t1, and the N^{th} transmitter 4tN) would not be interfered with each other.

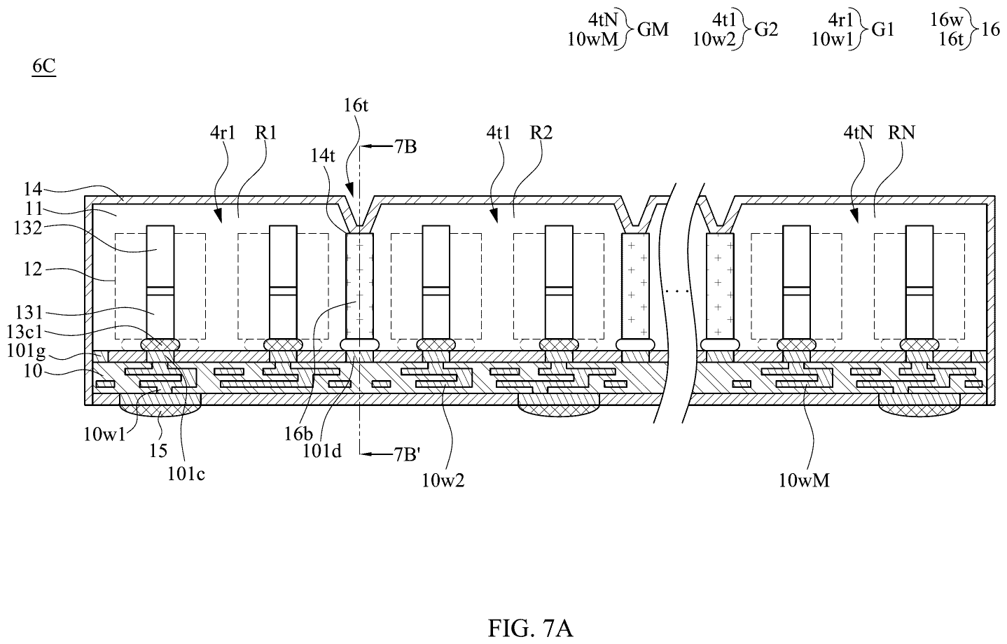

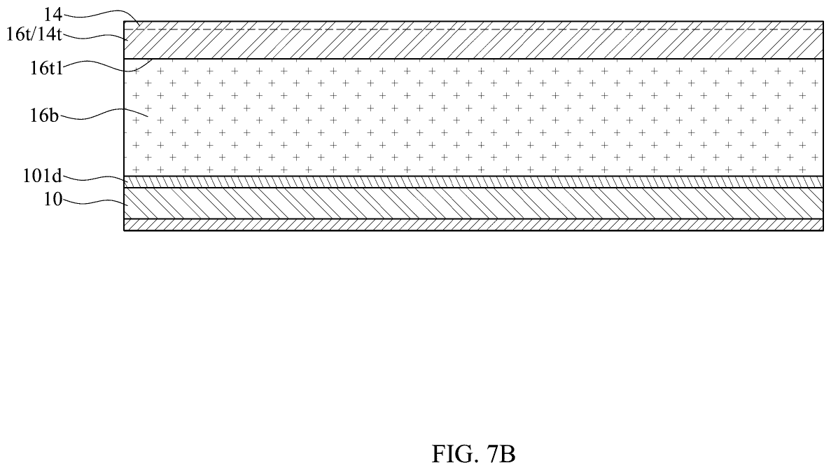

FIG. 7A is a cross-section of a semiconductor module 6C according to some embodiments of the present disclosure. The semiconductor module 6C of FIG. 7A is similar to the semiconductor module 6B in FIG. 6A. Therefore, some detailed descriptions may refer to corresponding preceding paragraphs and are not repeated hereinafter for conciseness, with differences therebetween as follows.

The compartment 16 may include a plurality of metal blocks 16b rather than the conductive wires 16w. The trenches 16t may be disposed over the metal blocks 16b. Each of the trenches 16t may be connected to a respective one of the metal blocks 16b. The metal blocks 16b may be mounted on the landing pads 101d by a pick-and-place approach. The metal blocks 16b may be copper, gold, silver, aluminum, titanium, tantalum, or the like.

FIG. 7B is a cross-section along line 7B-7B′ of FIG. 7A. Each of the trenches 16t may extend along a respective one of the metal blocks 16b. Each of the trenches 16t may have a bottom surface 16t1 in contact with one of the metal blocks 16b. Owing to the shielding of the compartment 16, the signals processed in the regions R1, R2, . . . , RN (or the first receiver 4r1, the first transmitter 4t1, and the N^{th} transmitter 4tN) will not interfere with each other.

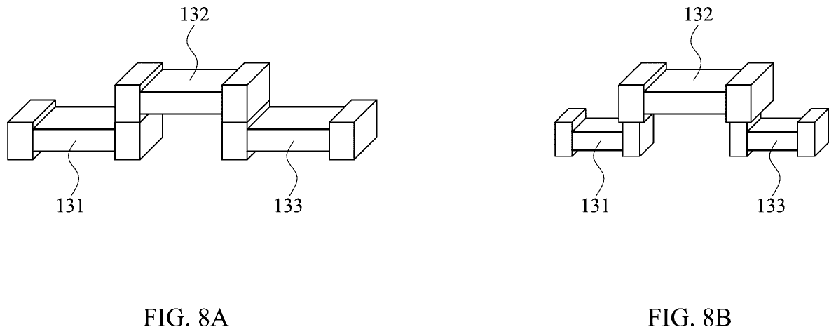

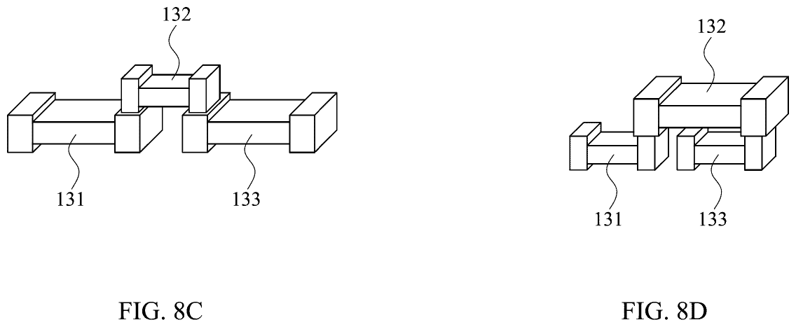

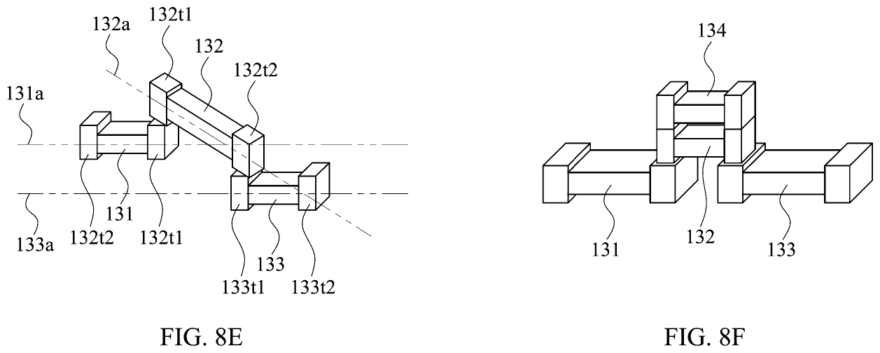

FIGS. 8A, 8B, 8C, 8D, 8E, and 8F are three-dimensional views of a passive component (e.g., passive components 13) according to some embodiments of the present disclosure. The passive components 13 may include a first passive component 131, a second passive component 132, and a third passive component 133. The second passive component 132 may be stacked over the first passive component 131 and the third passive component 133. FIGS. 8A, 8B, 8C, 8D, 8E, and 8F illustrate various embodiments of the arrangement of the stacked passive components 131, 132, and 133.

As shown in FIG. 8A, passive component 132 may be stacked over passive components 131 and 133. Passive components 131, 132, and 133 of the passive components 13 may be substantially the same size.

As shown in FIG. 8B, passive component 132 may be stacked over passive components 131 and 133. The passive component 132 may be larger than passive components 131 and 133.

As shown in FIG. 8C, passive component 132 may be stacked over passive components 131 and 133. Passive component 132 may be smaller than passive components 131 and 133.

As shown in FIG. 8D, passive component 132 may be larger than passive components 131 and 133. Passive component 133 may be directly under passive component 132. Passive component 132 may completely overlap passive component 133.

As shown in FIG. 8E, the first passive component 131 may have a first axis 131a and the second passive component 132 may have a second axis 132a. The first axis 131a may extend through the terminals 131t1 and 131t2 of the first passive component 131 and be parallel with a lateral surface of the first passive component 131. The second axis 132a may extend through the terminals 132t1 and 132t2 of the second passive component 132 and be parallel with a lateral surface of the second passive component 132. The first axis 131a may intersect with the second axis 132a. The first axis 131a and the second axis 132a may not be parallel to each other. The first axis 131a of the first passive component 131 and the second axis 132a of the second passive component 132 form a positive angle or a negative angle. The third passive component 133 may have a third axis 133a. The third axis 133a may extend through the terminals 133t1 and 133t2 of the third passive component 133 and be parallel with a lateral surface of the third passive component 133. The third axis 133a of the third passive component 133 and the second axis 132a of the second passive component 132 form a positive angle or a negative angle. The third axis 133a may intersect with the second axis 132a. The third axis 133a and the second axis 132a may not be parallel to each other. The third axis 133a may be parallel to the first axis 131a.

As shown in FIG. 8F, the passive components 13 may further include a fourth passive component 134 stacked on the second passive component 132. The fourth passive component 134 and the second passive component 132 may be capacitors connected in parallel. As such, the capacitance of the passive components 13 can be increased.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to +5%, less than or equal to +4%, less than or equal to +3%, less than or equal to +2%, less than or equal to #1%, less than or equal to +0.5%, less than or equal to +0.1%, or less than or equal to +0.05%. For example, a first numerical value can be deemed to be “substantially” the same or equal to a second numerical value if the first numerical value is within a range of variation of less than or equal to +10% of the second numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, “substantially” perpendicular can refer to a range of angular variation relative to 90° that is less than or equal to +10°, such as less than or equal to +5°, less than or equal to +4°, less than or equal to +3°, less than or equal to +2°, less than or equal to +1°, less than or equal to +0.5°, less than or equal to +0.1°, or less than or equal to +0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor module, comprising:
a carrier;
a plurality of passive components disposed over the carrier;
an electronic component disposed over the carrier and configured to clamp a voltage of the semiconductor module; and
an encapsulation layer covering and contacting the plurality of passive components and the electronic component.

2. The semiconductor module of claim 1, wherein the passive components comprise a first passive component and a second passive component, wherein a first axis of the first passive component and a second axis of the second passive component are not parallel to each other.

3. The semiconductor module of claim 2, wherein the passive components comprise a third passive component, wherein a third axis of the third passive component is parallel to the first axis.

4. The semiconductor module of claim 1, further comprising a shield disposed between the passive components and the electronic component.

5. The semiconductor module of claim 1, wherein the encapsulation layer has a first top surface higher than a second top surface of the passive components and a third top surface of the electronic component.

6. The semiconductor module of claim 1, wherein the passive components comprise a resistor and a capacitor.

7. The semiconductor module of claim 6, wherein the electronic component comprises a terminal connected to a terminal of the resistor.

8. The semiconductor module of claim 7, wherein the encapsulation layer vertically, with respect to the carrier, covers an electrical transmission path connecting the terminal of the electronic component and the terminal of the resistor.

9. The semiconductor module of claim 6, wherein the capacitor is disposed over the resistor, and a first elevation of a top surface of the capacitor is higher than or substantially the same as a second elevation of a top surface of the electronic component with respect to the carrier.

10. The semiconductor module of claim 1, further comprising a shield covering the encapsulation layer.

11. The semiconductor module of claim 1, wherein the electronic component comprises an electrostatic discharge (ESD) device.

12. The semiconductor module of claim 1, wherein the passive components comprise an electrical overstress (EOS) circuit.

13. A semiconductor module, comprising:
a carrier comprising a first wiring structure and a second wiring structure;
a first device electrically connected to the first wiring structure, wherein the first device and the first wiring structure collectively define a first group; and
a second device electrically connected to the second wiring structure, wherein the second device and the second wiring structure collectively define a second group,
wherein the first group operates independent of the second group.

14. The semiconductor module of claim 13, wherein the first wiring structure is free from being electrically connected to the second device, and the second wiring structure is free from being electrically connected to the first device.

15. The semiconductor module of claim 13, wherein the first group is configured to process a first signal transmitted from a first external electronic component to a second external electronic component, and the second group is configured to process a second signal transmitted from the second external electronic component to the first external electronic component.

16. The semiconductor module of claim 13, further comprising a shield disposed in the carrier and between the first wiring structure and the second wiring structure.

17. An electronic system, comprising:
a plurality of passive components;
a first electronic component configured to clamp a voltage of the electronic system and having a first terminal; and
an encapsulation layer covering and contacting the plurality of passive components and the first electronic component; and
a second electronic component electrically connected to the first terminal.

18. The electronic system of claim 17, further comprising a third electronic component electrically connected to a terminal of the passive components.

19. The electronic system of claim 18, further comprising a device electrically connected to the second electronic component, wherein the second electronic component is configured to synchronize a first signal transmitted from the third electronic component to the device and a second signal transmitted from the device to the third electronic component.

20. The electronic system of claim 18, wherein the first electronic component is configured to block a signal from the third electronic component to the second electronic component when a voltage difference between the first terminal and a second terminal of the electronic component exceeds a predetermined value, wherein the signal is transmitted through the passive components and the first electronic component.
